(19) United States
(12) Patent Application Publication
(10) Pub. No.: US 2008/0124830 A1
(43) Pub. Date: May 29, 2008

(54) METHOD OF MANUFACTURING IMAGE SENSOR

(76) Inventor: Sang-Gi Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/939,309

(22) Filed: Nov. 13, 2007

(30) Foreign Application Priority Data
Nov. 29, 2006 (KR) 10-2006-0118981
Dec. 29, 2006 (KR) 10-2006-0137340

(51) Int. Cl. H01L 25/04

(52) U.S. Cl. 438/59; 257/E25.004

(57) ABSTRACT

A method of manufacturing a CMOS image sensor in which a photodiode region and a floating diffusion region can be formed without using a hard mask. Such a method can prevent misalignment between the photodiode region and a gate pattern region without using a hard maska and also prevent the passing of ions when performing an ion implantation process through a gate region.

The present application claims priority under 35 U.S.C. 119 to Korean Patent Application No. 10-2006-0118981, (filed on Nov. 29, 2006) and Korean Patent Application No. 10-2006-0137340, (filed on Dec. 29, 2006), which are each hereby incorporated by reference in their entirities.

### BACKGROUND

An image sensor is a semiconductor device used to convert optical images detected by the image sensor to electric signals. Image sensors may be classified as a charge coupled device (CCD) or a complementary metal oxide semiconductor (CMOS).

A CCD image sensor is provided with metal oxide silicon (MOS) capacitors that are spatially positioned within close proximity to each other and charge carriers are stored in and transferred to the capacitors.

A CMOS image sensor may be provided with a plurality of MOS transistors corresponding to pixels of a semiconductor device having a control circuit and a signal processing circuit as peripheral circuits. The pixel region may be provided with a plurality of photodiodes while the peripheral circuit region, which may surround the pixel region, may serve to detect signals detected in the pixel region. The control circuit and the signal processing unit may be integrated together to employ a switching method that detects output through the MOS transistors. In a CMOS image sensor, as light intensity of the photodiode increases, photosensitivity of the image sensor may be further enhanced.

The CCD image sensor is considered superior to the CMOS image sensor in terms of photosensitivity and noise reduction but has difficulty in achieving highly integrated density and low power consumption. Moreover, the CMOS image sensor is simpler to manufacture and can be more suitable for achieving highly integrated density and low power consumption. Accordingly, aspects of semiconductor fabricating technology have focused on developing a CMOS image sensor due to its qualities in addition to enhanced fabricating technology.

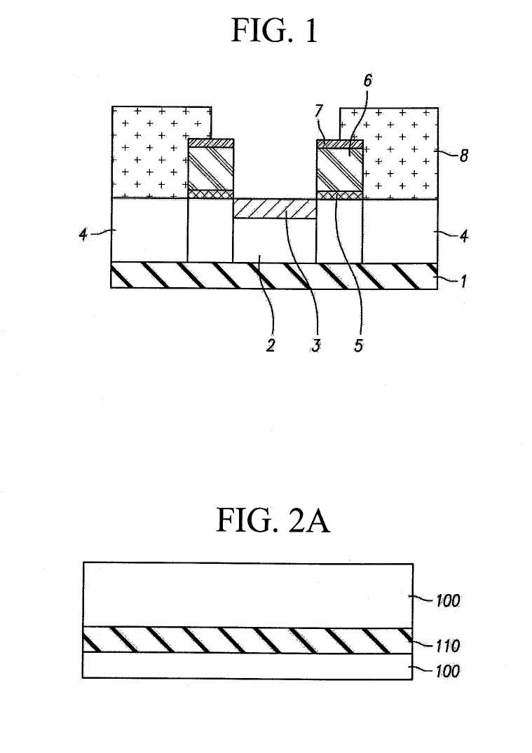

As illustrated in example FIG. 1, gate oxide film 5 may be formed on and/or over semiconductor substrate 1 into which a p-type dopant such as boron may be implanted. Polysilicon layer 6 may be formed on and/or over semiconductor substrate 1 including gate oxide film 5. Hard mask 7 may be formed on and/or over polysilicon layer 6, and a gate patterning process may be performed to form a gate.

After the gate is formed, in order to form a floating diffusion region, hard mask 7 and photoresist pattern 8 may be formed and an ion implantation process may also be performed using hard mask 7 and photoresist pattern 8, thereby forming floating diffusion regions 2, 3. Thereafter, in order form blue photodiode 4, another photoresist pattern for opening blue photodiode region 4 may be formed. When hard mask 7 is used, an etching process may be difficult to be performed and particles may occur.

In the method of manufacturing such a CMOS image sensor, ion implantation processes for forming blue photodiode 4 and floating diffusion regions 2, 3 may require high energy. However, when the ion implantation process is performed with high energy, it is important to prevent ions from passing through the region below a gate region. Accordingly, blue photodiode 4 may be formed by performing the photoresist process twice. However, since it is often difficult to perform the photoresist process twice, the process using hard mask 7 may be used. In this case, the etching process may become difficult and results in the generation of unwanted particles.

### SUMMARY

Embodiments relate to a method of manufacturing a vertical type CMOS image sensor in which a photodiode region and a floating diffusion region may be formed without use of a hard mask. Such a method can prevent misalignment between the photodiode region and a gate pattern region without using a hard mask. The method can also prevent the passing of ions when performing an ion implantation process through a gate region.

Embodiments relate to a method of manufacturing an image sensor that can include at least one of the following steps: forming a barrier layer in a semiconductor substrate; forming a first photoresist pattern over the semiconductor substrate; forming a gate pattern including a gate oxide film pattern and a polysilicon film pattern over the semiconductor substrate; forming a second photoresist pattern over the first photoresist pattern; forming a first floating diffusion region and a photodiode region in semiconductor substrate; removing the first photoresist pattern and the second photoresist pattern; forming a polyoxide film over the semiconductor substrate including the gate oxide film pattern and the polysilicon film pattern; forming third photoresist pattern over the semiconductor substrate including polyoxide film; and then forming a second floating diffusion region over the first floating diffusion region.

Embodiments relate to a method of manufacturing an image sensor that can include at least one of the following steps: forming at least one device isolation film in a semiconductor substrate; forming a barrier layer below the device isolation film by implanting a dopant into the semiconductor substrate; forming a pad oxide film over an upper portion of the semiconductor substrate and forming a first photoresist pattern for opening a photodiode region over the pad oxide film; implanting a dopant into a photodiode region using the first photoresist pattern as a mask and the device isolation film as an alignment key; removing the first photoresist pattern and forming a second photoresist pattern for opening a floating diffusion region over the pad oxide film; forming an n-type floating diffusion region and a p-type floating diffusion region in the floating diffusion region using the second photoresist pattern as masks; removing the second photoresist pattern; forming a polysilicon film over the pad oxide film; forming a third photoresist pattern over the polysilicon film; and then forming a gate pattern using a third photoresist pattern as a mask.

### DRAWINGS

Example FIG. 1 illustrates a method of manufacturing an image sensor.

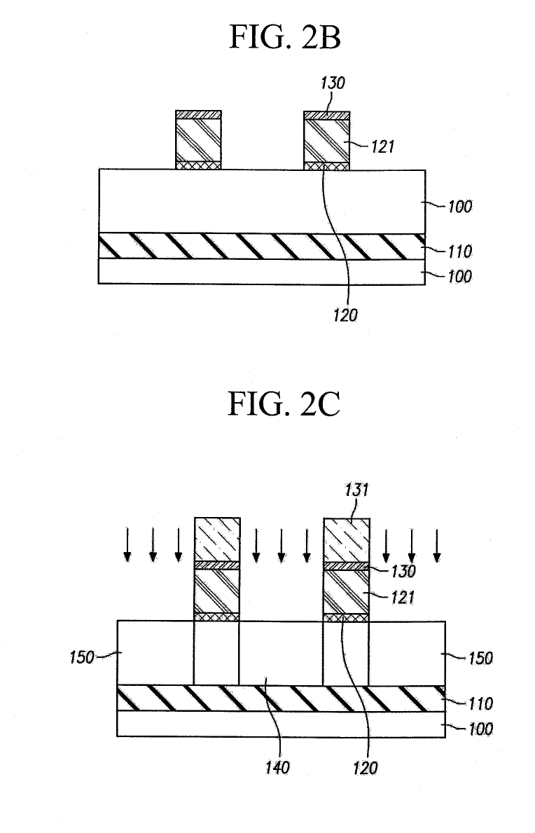

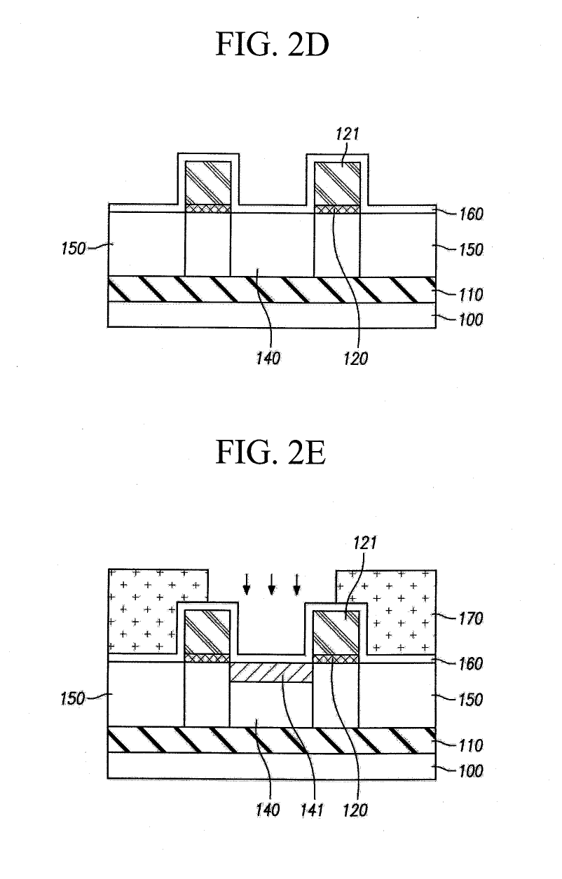

Example FIGS. 2A to 2E illustrate a method of manufacturing an image sensor, in accordance with embodiments.

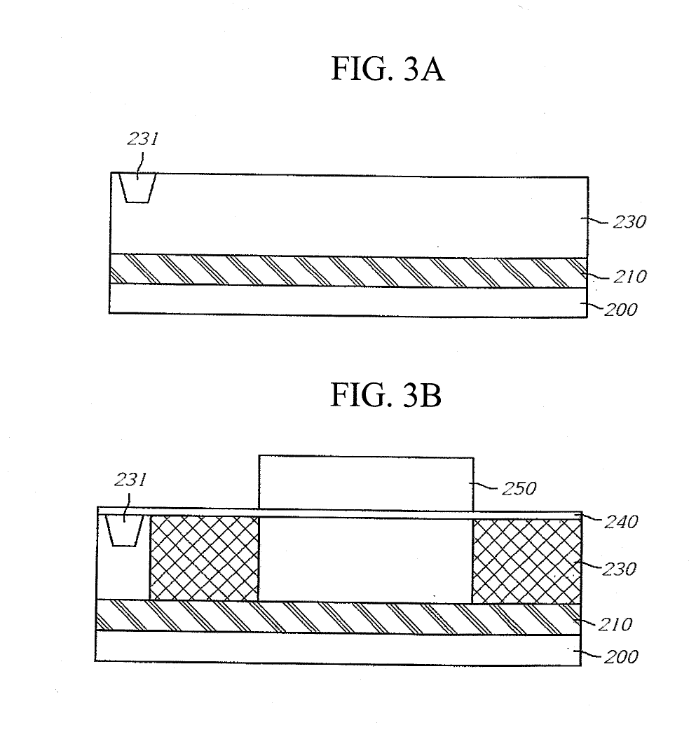

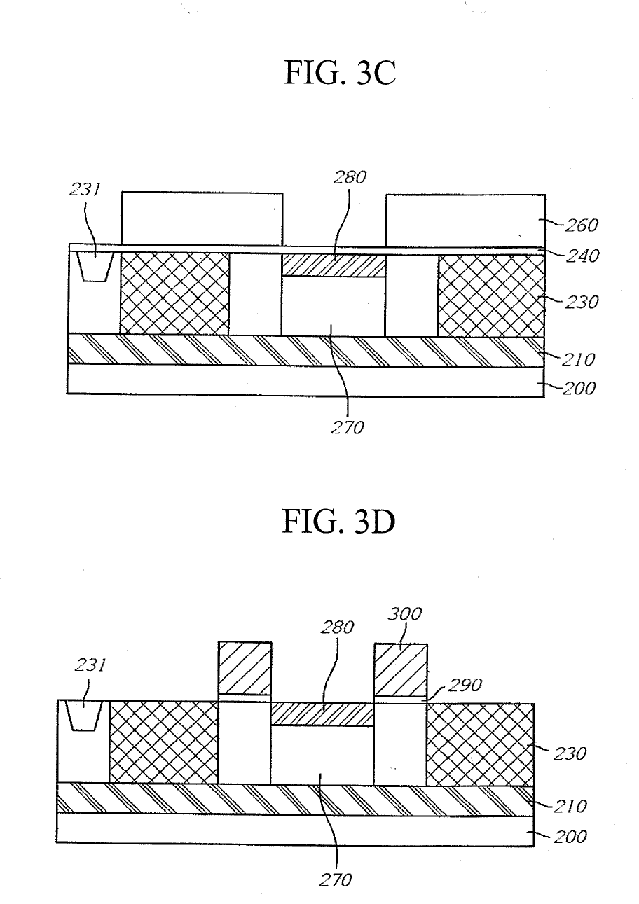

Example FIGS. 3A to 3D illustrate a method of manufacturing an image sensor, in accordance with embodiments.

### DESCRIPTION

As illustrated in example FIG. 2A, in accordance with embodiments a method of manufacturing an image sensor can include forming barrier layer 110 on and/or over semiconductor substrate 100. Barrier layer 110 can be formed by implanting a p-type dopant such as boron into semiconductor substrate 100.

After formation of barrier layer 110, first photoresist pattern 130 can be formed on and/or over semiconductor substrate 100. First photoresist pattern 130 can be formed by sequentially depositing a gate oxide film and a polysilicon film on and/or over semiconductor substrate 100.

As illustrated in example FIG. 2B, a gate pattern including gate oxide film pattern 120 and polysilicon film pattern 121 can be formed by performing a patterning process including an etching process and an ashing process using first photoresist pattern 130.

As illustrated in example in FIG. 2C, second photoresist pattern 131 can be formed on and/or over first photoresist pattern 130. Second photoresist pattern can be formed by coating a photoresist on and/or over semiconductor substrate 100 without removing first photoresist pattern 130, and performing development, exposure and etching processes. Alternatively, a structure without second photoresist pattern 131 may be provided by forming first photoresist pattern 130 having substantially the same thickness as a dual first photoresist pattern 130 and second photoresist pattern 131 structure.

Next, n-type floating diffusion region 140 and photodiode region 150 may be formed in semiconductor substrate 100 by implanting an n-type dopant into a portion of semiconductor substrate 100 located vertically above barrier layer 110 using first photoresist pattern 130 and second photoresist pattern 131 as masks. Photodiode region 150 can have a laminated structure including a red photodiode region, a green photodiode region and a blue diode region provided on and/or over the uppermost surface of barrier layer 110 of semiconductor substrate 100.

As illustrated in example FIG. 2D, after formation of n-type floating diffusion region 140 and photodiode region 150, first photoresist pattern 130 and second photoresist pattern 131 can be removed using an ashing process. Polyoxide film 160 can be deposited on and/or over semiconductor substrate 100 including gate oxide film pattern 120 and polysilicon film pattern 121. In a subsequent process of implanting a p-type dopant, the amount of the implanted p-type dopant can be adjusted by the thickness of polyoxide film 160.

As illustrated in example FIG. 2E, after formation of polyoxide film 160, third photoresist pattern 170 for opening only n-type floating diffusion region 140 can be formed on and/or over poly oxide film 160. A p-type dopant can be implanted through third photoresist pattern 170 such that p-type floating diffusion region 141, into which a p-type dopant can be implanted, is formed on and/or over n-type floating diffusion region 140.

Accordingly, a method of manufacturing an image sensor including n-type floating diffusion region 140, p-type floating diffusion region 141 and blue photodiode region 150 can be formed in semiconductor substrate 100 by performing processes of implanting dopants using first photoresist pattern 130, second photoresist pattern 131 and third photoresist pattern 170 as masks. Moreover, such dopants can be prevented from passing through the gate pattern including gate oxide film pattern 120 and polysilicon film pattern 121.

As illustrated in example FIG. 3A, in accordance with embodiments a method of manufacturing an image sensor can include forming device isolation film 231 in upper portion 230 of semiconductor substrate 200. Device isolation film 231 can serve as an alignment key and be formed using a shallow trench isolation (STI) process.

After formation of device isolation film 231, p-type barrier layer 210 can be formed in semiconductor substrate 200. P-type barrier layer 210 can be formed by implanting a p-type dopant such as boron into semiconductor substrate 200.

As illustrated in example FIG. 3B, after formation of p-type barrier layer 210 in semiconductor substrate 200, pad oxide film 240 can be formed on and/or over upper portion 230 of semiconductor substrate 200 including device isolation film 231. Pad oxide film 240 can be formed by depositing an oxide film on and/or over upper portion 230 of semiconductor substrate 200 using a chemical vapor deposition (CVD) method. A photoresist can then be coated on and/or over pad oxide film 240 and is patterned to form first photoresist pattern 250.

After formation of first photoresist pattern 250, a blue photodiode region can be formed by implanting a dopant into upper portion 230 of semiconductor substrate 200 using first photoresist pattern 250 as a mask and also using device isolation film 231 as an alignment key. Accordingly, the dopant for the blue photodiode can be accurately implanted into the blue photodiode region of upper portion 230 of semiconductor substrate using device isolation film 231 as the alignment key.

As illustrated in example FIG. 3C, after formation of the blue photodiode region, an ashing process can be performed to remove first photoresist pattern 250. A photoresist can be coated on and/or over pad oxide film 240 and can then be developed, exposed and etched to form second photoresist pattern 260 on and/or over pad oxide film 240. Second photoresist pattern 260 can serve to open floating diffusion regions 270, 280.

After formation of second photoresist pattern 260, n-type floating diffusion region 270 can be formed by implanting an n-type dopant using second photoresist pattern 260 as a mask. Subsequently, a p-type dopant can be implanted using second photoresist pattern 260 as a mask to form p-type floating diffusion region 280 on and/or over n-type floating diffusion region 270. The thickness of pad oxide film 240 can be used to adjust the amount of p-type dopant implanted into n-type floating diffusion region 270.

As illustrated in example FIG. 3D, after formation of p-type floating diffusion region 280, an ashing process can be performed to remove second photoresist pattern 260. A polysilicon film can then be deposited on and/or over pad oxide film 240. A third photoresist pattern for forming a gate pattern can be formed on and/or over the deposited polysilicon film, and a patterning process can be performed to form the gate pattern including pad oxide film pattern 290 and polysilicon film pattern 300.

Accordingly, a method of manufacturing an image sensor including n-type floating diffusion region 270, p-type floating diffusion region 280 and the blue photodiode region can be formed in upper portion 230 of semiconductor substrate 200 by performing processes of implanting dopants using first photoresist pattern 250 and second photoresist pattern 260 as masks. Moreover, such dopants can be prevented from passing through the gate pattern including gate oxide film pattern 290 and polysilicon film pattern 300.

In accordance with embodiments, misalignment can be prevented between the blue photodiode region and the gate pattern region by using device isolation film 231 as an alignment key. Also, ions simultaneously implanted into floating diffusion regions 270, 280 and the blue photodiode region using a high energy ion implantation process can be prevented from passing through a gate region. Even still, the amount of dopant implanted into floating diffusion regions 270, 280 can be adjusted using the thickness of pad oxide film 240 to easily control a junction depth.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a barrier layer in a semiconductor substrate;
forming a first photoresist pattern over the semiconductor substrate;
forming a gate pattern including a gate oxide film pattern and a polysilicon film pattern over the semiconductor substrate;
forming a second photoresist pattern over the first photoresist pattern;
forming a first floating diffusion region and a photodiode region in semiconductor substrate;
removing the first photoresist pattern and the second photoresist pattern;
forming a polyoxide film over the semiconductor substrate including the gate oxide film pattern and the polysilicon film pattern;
forming third photoresist pattern over the semiconductor substrate including polyoxide film; and then
forming a second floating diffusion region over the first floating diffusion region.

2. The method of claim 1, wherein forming the barrier layer comprises implanting a p-type dopant into the semiconductor substrate.

3. The method of claim 2, wherein the p-type dopant comprises boron.

4. The method of claim 1, wherein forming the first photoresist pattern comprises sequentially depositing a gate oxide film and a polysilicon film over the semiconductor substrate.

5. The method of claim 1, wherein forming a gate pattern comprises performing a patterning process including an etching process and an ashing process using the first photoresist pattern as a mask.

6. The method of claim 1, wherein forming the second photoresist pattern comprises:
coating a photoresist over the semiconductor substrate including the first photoresist pattern; and then
performing development, exposure and etching processes on the photoresist.

7. The method of claim 1, wherein the first floating diffusion region comprises an n-type floating diffusion region.

8. The method of claim 1, wherein the photodiode region is provided over the uppermost surface of the barrier layer.

9. The method of claim 8, wherein the photodiode region has a laminated structure including a red photodiode region, a green photodiode region and a blue diode region.

10. The method of claim 9, wherein forming the n-type floating diffusion region and the photodiode region comprises implanting an n-type dopant into a portion of the semiconductor substrate located vertically above the barrier layer using the first photoresist pattern and the second photoresist pattern as masks.

11. The method of claim 1, wherein the first photoresist pattern and the second photoresist pattern are removed using an ashing process.

12. The method of claim 1, wherein the second floating diffusion region comprises a p-type floating diffusion region.

13. The method of claim 12, wherein forming the p-type diffusion region comprises implanting a p-type dopant using the third photoresist pattern as a mask.

14. The method according to claim 13, wherein the amount of dopant implanted for forming the second floating diffusion region is adjustable using the polyoxide film.

15. A method comprising:
forming at least one device isolation film in an upper portion of a semiconductor substrate;
forming a p-type barrier layer in the semiconductor substrate and below the upper portion of the semiconductor substrate;
forming a pad oxide film over the upper portion of the semiconductor substrate including the device isolation film;
forming a first photoresist pattern over the pad oxide film;
forming a blue photodiode region in the upper portion of the semiconductor substrate by implanting a dopant using the first photoresist pattern as a mask and also using the at least one device isolation film as an alignment key;
removing the first photoresist pattern;
forming a second photoresist pattern over the pad oxide film;
forming a first floating diffusion region in the upper portion of the semiconductor substrate;
forming a second floating diffusion region over the first floating region in the upper portion of the semiconductor substrate by implanting a p-type dopant using the second photoresist pattern as a mask, wherein amount of p-type dopant is adjustable using the thickness of the pad oxide film;
removing the second photoresist pattern; and then
forming a gate pattern including a pad oxide film pattern and a polysilicon film pattern.

16. The method of claim 15, wherein the at least one device isolation film is formed using a shallow trench isolation process.

17. The method of claim 15, wherein the first floating diffusion region comprises an n-type floating diffusion region.

18. The method of claim 17, wherein forming the first floating diffusion region comprises implanting an n-type dopant using the second photoresist pattern as a mask.

19. A method comprising:
forming at least one device isolation film in a semiconductor substrate;
forming a barrier layer below the device isolation film by implanting a dopant into the semiconductor substrate;
forming a pad oxide film over an upper portion of the semiconductor substrate and forming a first photoresist pattern for opening a photodiode region over the pad oxide film;
implanting a dopant into a photodiode region using the first photoresist pattern as a mask and the device isolation film as an alignment key;
removing the first photoresist pattern and forming a second photoresist pattern for opening a floating diffusion region over the pad oxide film;
forming an n-type floating diffusion region and a p-type floating diffusion region in the floating diffusion region using the second photoresist pattern as masks;
removing the second photoresist pattern;
forming a polysilicon film over the pad oxide film;
forming a third photoresist pattern over the polysilicon film; and then
forming a gate pattern using a third photoresist pattern as a mask.
